(19) United States
(12) Patent Application Publication
(10) Pub. No.: US 2022/0141982 A1
(43) Pub. Date: May 5, 2022

(54) ENGINEERING COMMUNICATION TRANSFER DEVICE AND SYSTEM

(71) Applicant: China Institute of Water Resources and Hydropower Research, Beijing (CN)

(72) Inventors: Yunhui JIANG, Beijing (CN); Zhengchao Lu, Beijing (CN); Yongrong Qiu, Beijing (CN); Sen Gao, Beijing (CN); Mingzhe Luo, Beijing (CN); Hui Li, Beijing (CN); Yue Zhao, Beijing (CN); Demin Xue, Beijing (CN); Zhenhong Wang, Beijing (CN)

(21) Appl. No.: 17/090,450

(22) Filed: Nov. 5, 2020

(51) Int. Cl. H05K 5/02; H03K 17/96

(52) U.S. Cl. CPC H05K 5/0247; H03K 17/96

(57) ABSTRACT

The disclosure provides an engineering communication transfer device and system. The device includes a communication transfer box. The communication transfer box includes a communication input terminal, a first communication output terminal, and a second communication output terminal; the communication input terminal is connected to a communication cable, and the communication cable is connected to a safety monitoring instrument; the first communication output terminal is connected to an information acquisition instrument, and the second communication output terminal is connected to a cable of an external access device; the communication transfer box is configured to connect the communication cable to the second communication output terminal when an external access device is connected to the second communication output terminal. The disclosure achieves beneficial effects of being simple, convenient and efficient in intermediate measurement and reading, without damaging a transmission line.

### TECHNICAL FIELD

The disclosure relates to the field of measurement and communication technologies, and in particular, to an engineering communication transfer device and system.

### BACKGROUND

At present, most of the engineering safety monitoring instruments (such as various sensors) need to be connected to secondary instruments or automatic acquisition devices to measure a target physical quantity of a measured object.

The engineering safety monitoring instruments and the secondary instruments or automatic acquisition devices are directly connected by using cables. However, during data acquisition, sometimes some data needs to be acquired manually at a specific position in a middle section of a transmission line. In this case, a usual method is to cut a cable, and then connect the cable to an instrument for manual data acquisition. However, this method is very laborious and causes great damage to the transmission line.

### SUMMARY

In view of this, the disclosure provides an engineering communication transfer device and system to facilitate data acquisition in a middle section of a transmission line.

In a first aspect, an embodiment of the disclosure provides an engineering communication transfer device, including: a communication transfer box, where the communication transfer box includes: a communication input terminal, a first communication output terminal, and a second communication output terminal; the communication input terminal is connected to a communication cable, where the communication cable is connected to a safety monitoring instrument; the first communication output terminal is connected to an information acquisition instrument; the second communication output terminal is connected to a cable of an external access device; and the communication transfer box is configured to connect the communication cable to the second communication output terminal when an external access device is connected to the second communication output terminal.

With reference to the first aspect, the disclosure provides a first possible implementation of the first aspect, where the communication transfer box is detachably connected to a control box; and after connected to the control box, the communication transfer box receives a control signal sent by the control box; and in response to the control signal, controls the communication cable to connect to the external access device, so that the external access device is able to obtain data measured by the safety monitoring instrument.

With reference to the first possible implementation of the first aspect, the disclosure provides a second possible implementation of the first aspect, where the communication transfer box includes: a control switch, where the control switch is connected to the communication input terminal, and the control switch is connected to the first communication output terminal in a normal state, and switches to be connected to the second communication output terminal upon receiving of the control signal from the control box.

With reference to the second possible implementation of the first aspect, the disclosure provides a third possible implementation of the first aspect, where there are a plurality of control switches, which are respectively connected to internal core wires of the communication cable; the first communication output terminal includes a plurality of first cable core wire connection points, and the second communication output terminal includes a plurality of second cable core wire connection points; the first cable core wire connection point is used to connect to an internal core wire of a first cable, and the second cable core wire connection point is used to connect to an internal core wire of a second cable; the first cable is a cable connecting the first communication output terminal and the information acquisition instrument, and the second cable is a cable connecting the second communication output terminal and the external access device.

With reference to the second possible implementation of the first aspect, the disclosure provides a fourth possible implementation of the first aspect, where the control switch is a relay.

With reference to the first possible implementation of the first aspect, the disclosure provides a fifth possible implementation of the first aspect, where the control box is provided with an external access device interface, and the control box is connected to the external access device through the external access device interface.

With reference to the first possible implementation of the first aspect, the disclosure provides a sixth possible implementation of the first aspect, where the communication transfer box is further configured to control the communication cable to connect to the external access device, and cut off a connection to the information acquisition instrument.

With reference to the first possible implementation of the first aspect, the disclosure provides a seventh possible implementation of the first aspect, where the control box includes a processor, the processor is connected to the communication transfer box; a touch-sensitive switch is provided on a housing of the control box, and the touch-sensitive switch is configured to detect a touch operation of a user, and send a detected touch signal to the processor; the processor generates a control signal based on the touch signal, and sends the control signal to the communication transfer box; and in response to the control signal, the communication transfer box controls the communication cable to connect to the external access device.

With reference to the seventh possible implementation of the first aspect, the disclosure provides an eighth possible implementation of the first aspect, where the processor is further configured to detect a connection status of the external access device, and after determining that a connection is valid, control the control switch to connect to the second communication output terminal.

In a second aspect, the disclosure provides an engineering data acquisition and transmission system, including: a safety monitoring instrument, a communication cable, an information acquisition instrument, and any one of the engineering communication transfer device mentioned in the first aspect, where the safety monitoring instrument is connected to the communication cable, the communication cable is connected to the engineering communication transfer device, and the engineering communication transfer device is further connected to the information acquisition instrument.

In the engineering communication transfer device and system provided by examples of the disclosure, a communication transfer box is used for a communication cable. In the prior art, when data needs to be acquired manually in the middle of a communication line, a communication cable can only be connected to an external device by cutting the cable. By contrast, the disclosure has the beneficial effects of being simple, convenient, and efficient without damaging the transmission line.

In order to make the above objectives, features, and advantages of the disclosure more understandable, the following is described in detail by using preferred examples with reference to the accompanying drawings.

### BRIEF DESCRIPTION OF DRAWINGS

To describe the technical solutions in the examples of the disclosure more clearly, the following briefly describes the accompanying drawings required for describing the examples. It should be understood that, the following accompanying drawings show merely some examples of the disclosure, and therefore should not be regarded as a limitation on the scope. A person of ordinary skill in the art may still derive other related drawings from these accompanying drawings without creative efforts.

FIG. 1 is a schematic structural diagram of an engineering data acquisition and transmission system in the prior art.

FIG. 2 is a schematic structural diagram of an engineering communication transfer device according to an example of the disclosure.

FIG. 3 is a schematic structural diagram of an engineering communication transfer device according to an example of the disclosure.

FIG. 4 is a schematic structural diagram of an engineering data acquisition and transmission system according to another example of the disclosure.

### DETAILED DESCRIPTION OF PREFERRED EMBODIMENTS

In order to make the objectives, technical solutions and advantages of the examples of the disclosure clearer, the following clearly and completely describes the technical solutions in the examples of the disclosure with reference to accompanying drawings in the examples of the disclosure. Apparently, the described examples are some rather than all of the examples. Generally, components of examples of the disclosure described and shown in the accompanying drawings may be arranged and designed in various manners. Therefore, the following detailed description of the examples of the disclosure in the accompanying drawings is not intended to limit the protection scope of the disclosure, but merely represent selected examples of the disclosure. All other examples obtained by a person of ordinary skill in the art based on the examples of the disclosure without creative efforts shall fall within the protection scope of the disclosure.

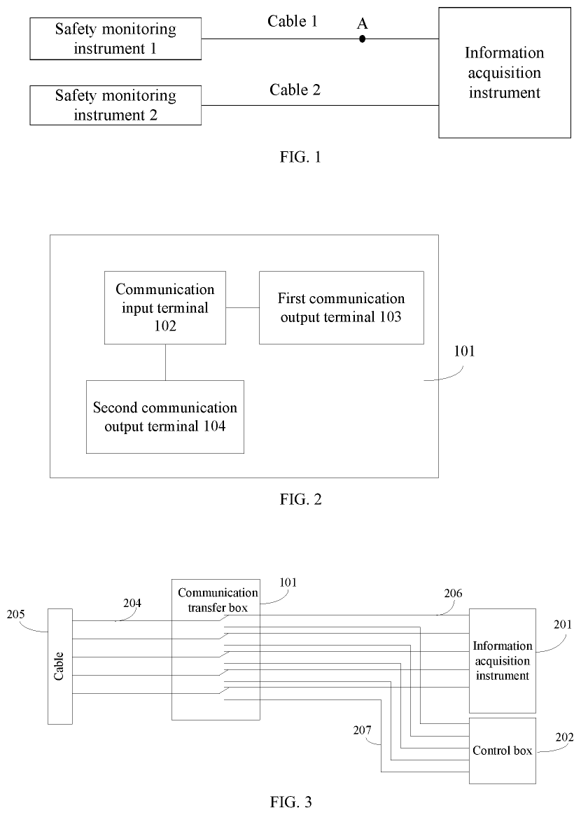

At present, most engineering safety monitoring instruments (such as strain gauges, piezometers, and other types of sensors) in civil engineering, water conservancy, and hydropower projects need to be connected to secondary instruments or automatic acquisition devices to measure a target physical quantity of a measured object. Generally, the engineering safety monitoring instrument and the secondary instrument or automatic acquisition device are directly connected through a cable. As shown in FIG. 1, if data needs to be manually measured at a position A in a middle section of a transmission line, a cable needs to be cut and reconnected to an external device. This method damages the communication cable and takes time and effort. In view of this, examples of the disclosure provide an engineering communication transfer device and system.

An example in FIG. 2 provides an engineering communication transfer device. The device includes: a communication transfer box 101, where the communication transfer box includes: a communication input terminal 102, a first communication output terminal 103, and a second communication output terminal 104.

The communication input terminal is connected to a communication cable, and the communication cable is further connected to a safety monitoring instrument.

The first communication output terminal 103 is connected to an information acquisition instrument, where the information acquisition instrument may be a secondary device or an automatic information acquisition device (such as a computer or a host computer). The second communication output terminal 104 is connected to a cable of an external access device, where the external access device may be a measuring and reading instrument.

The communication transfer box is configured to connect the communication cable and the second communication output terminal when an external access device is directly or indirectly connected to the second communication output terminal, so that the external device can obtain monitoring data from the safety monitoring instrument.

Specifically, as shown in FIG. 3, the communication transfer box 101 and a control box 202 are detachably connected; and the communication transfer box is provided with an interface for connecting to the control box.

The control box 202 is provided with an external access device interface. The control box 202 is connected to the external access device through the external access device interface.

After connected to the control box, the communication transfer box receives a control signal sent by the control box. In response to the control signal, the communication transfer box controls the communication cable to connect to the external access device, so that the external access device is able to obtain data measured by the safety monitoring instrument.

Specifically, the communication transfer box 101 includes: a control switch, where the control switch is connected to the communication input terminal, and the control switch is connected to the first communication output terminal in a normal state, to ensure that the information acquisition instrument collects monitoring data from the safety monitoring instrument in the normal state. The communication transfer box 101 switches to be connected to the second communication output terminal after receiving the control signal from the control box, so that the external access device can collect data measured by the safety monitoring instrument.

As shown in FIG. 3, there are a plurality of control switches, which are respectively connected to internal core wires 204 of a communication cable. The communication cable is a cable 205 connected to the safety monitoring instrument. The first communication output terminal 103 includes a plurality of first cable core wire connection points, and the second communication output terminal 104 includes a plurality of second cable core wire connection points. The first cable core wire connection point is used to connect to an internal core wire of a first cable 206, and the second cable core wire connection point is used to connect to an internal core wire of a second cable 207. The first cable 206 is a cable connecting the first communication output terminal and the information acquisition instrument 201, and the second cable 207 is a cable connecting the second communication output terminal of the communication transfer box and the external access device. In this example, the second cable is first connected to the control box, and then connected to the external access device through the control box.

In another possible example, the communication transfer box may be provided with a communication input terminal, a first communication output terminal, a second communication output terminal, and a control box connection terminal. The communication input terminal is connected to a communication cable, where the communication cable is a cable connected to the safety monitoring instrument. The first communication output terminal is connected to the information acquisition instrument. The second communication output terminal is configured to be directly connected to the external access device. The control box connection terminal is connected to the control box. The communication transfer box may be connected to the control box and the external access device. After the control box and the external access device are connected to the communication transfer box, the control box controls a switch in the communication transfer box to enable connectivity with the internal core wire of the second cable, so that the external access device can collect the data monitored by the safety monitoring instrument.

Alternatively, in another possible example, the control box may be directly disposed inside the communication transfer box. It should be noted that this is only an example for illustration. In actual implementation, the communication transfer box, the control box, and the external access device may have various location settings and connection methods; therefore, the foregoing implementation should not be regarded as a limitation to the disclosure.

For example, the control switch is a relay.

In this example, the control switch switches to enable connectivity with the second cable core wire connection point of the second output terminal and disable connectivity with the first output terminal. This prevents mutual effect between data obtaining by the information acquisition instrument and data obtaining by the external access device.

In the foregoing example, the communication transfer box may set a quantity of communication input terminals, that is, a quantity of channels, which is usually 16. Each channel is connected to an instrument cable. When a state of the control switch does not change, each channel is connected to the remote information acquisition instrument; after the control switch acts, each channel is connected to the external access device (measuring and reading instrument), and disconnects from the information acquisition instrument to avoid affecting the information acquisition instrument.

For example, in practical application, if data of a safety monitoring instrument connected to a fifth channel of the communication transfer box needs to be manually tested, the control box is used to switch to the fifth channel of the transfer box. At this time, the safety monitoring instrument connected to the fifth channel has been disconnected from the information acquisition instrument and connected to the control box, so that an external access device (measuring and reading instrument) connected to the control box reads data of the instrument connected to the fifth channel. By analogy, the control box controls the channel switching on the transfer box one by one to complete the measurement and reading.

The device provided in this example solves the need for measuring and reading data at a point in the middle of a data transmission line. It facilitates data measuring and reading at a middle point of the transmission line, without automatic recovery during measuring and reading. This greatly improves work efficiency, reduces work intensity, avoids damage to cables, and obtains significant economic benefits.

In a possible implementation, the foregoing control box includes: a processor, where the processor is connected to the communication transfer box, and specifically, connected to a control switch inside the communication transfer box. The control box further includes a housing, where the housing of the control box is provided with a touch-sensitive switch. The touch-sensitive switch is configured to detect a touch operation of a user, and send a detected touch signal to the processor. The processor receives the touch signal, generates a control signal based on the touch signal, and sends the control signal to the communication transfer box. In response to the control signal, the communication transfer box controls the communication cable to connect to the external access device. If the control switch is a relay, after receiving the touch signal, the processor controls a coil of the relay to be energized. In this case, a switch of the relay acts and switches to the second output terminal. The second output terminal is connected to the communication cable. Then, the external access device can collect data. For example, after the data acquisition of the external access device is completed, the user touches the housing of the control box again, and a touch signal is generated. After the processor receives this touch signal, it controls the relay to be deenergized, and resets the switch, so that the communication cable is connected to the first output terminal and the information acquisition instrument recovers to collect data.

As mentioned above, the processor is further configured to detect a connection status between the control box and the external access device, and after determining that the connection is successful, control the control switch to enable connectivity with the second communication output terminal. Specifically, the processor determines whether the following conditions are met at the same time: the touch signal is received; and the control box is connected to the external access device. When these two conditions are met at the same time, the processor controls an action of the control switch.

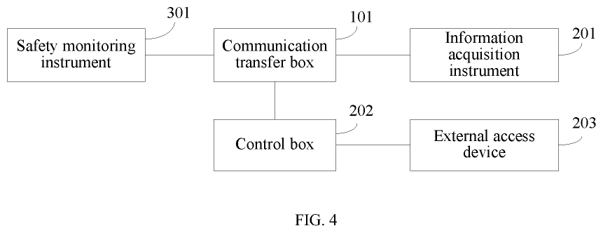

As shown in FIG. 4, an example of the disclosure provides an engineering data acquisition and transmission system. The system includes: a safety monitoring instrument 301, a communication cable, an information acquisition instrument 201, and at least one engineering communication transfer device according to any one of the foregoing examples. The safety monitoring instrument 301 is connected to the communication cable, and the communication cable is connected to the engineering communication transfer device. Preferably, the communication transfer box 101 in the device is connected to the control box 202, the control box 202 is further connected to an external access device, and the engineering communication transfer device is further connected to the information acquisition instrument 201.

In this example, when data needs to be manually acquired in a middle section of a transmission line, the control box is connected to the communication transfer box, and the external access device is connected to the control box. The control box controls the communication transfer box to cut off a communication connection between the safety monitoring instrument and the information acquisition instrument, and set up a communication connection between the safety monitoring instrument and the external access device, so that the external access device can obtain data monitored by the safety monitoring instrument. In this example, to allow the user to manually collect data at any position of the transmission line, communication transfer boxes may be arranged at different positions of the transmission line.

It should be noted that similar reference signs and letters represent similar items in the accompanying drawings below. Therefore, once an item is defined in one drawing, it does not need to be further defined and described in subsequent drawings.

In the description of the disclosure, it should be noted that orientations or position relationships indicated by terms “center”, “upper”, “lower”, “left”, “right”, “vertical”, “horizontal”, “inner”, “outer”, etc. are orientation or position relationships shown in the accompanying drawings, and these terms are only used to facilitate description of the disclosure and simplify the description, but not to indicate or imply that the mentioned apparatus or components must have a specific orientation or must be established and operated in a specific orientation, and thus these terms cannot be understood as a limitation to the disclosure. In addition, the terms such as “first”, “second”, and “third” are used only for the purpose of description and cannot be understood to indicate or imply relative importance.

In the description of the disclosure, it should be noted that, unless otherwise clearly specified and limited, meanings of terms “install”, “connected with”, and “connected to” should be understood in a board sense. For example, the connection may be a fixed connection, a removable connection, or an integral connection; may be a mechanical connection or an electrical connection; may be a direct connection or an indirect connection by using an intermediate medium; or may be intercommunication between two components. A person of ordinary skill in the art may understand specific meanings of the foregoing terms in the disclosure based on a specific situation.

Finally, it should be noted that the foregoing examples are merely specific implementations of the disclosure, and are used to describe rather than limiting the technical solutions of the disclosure. The protection scope of the disclosure is not limited thereto. Although the disclosure is described in detail with reference to the foregoing examples, it should be understood that a person of ordinary skill in the art can still make modifications to or readily figure out changes in the technical solutions described in the foregoing examples, or make equivalent substitutions on some technical features therein. These modifications, changes, or substitutions do not make the essence of the corresponding technical solutions depart from the spirit and scope of the technical solutions of the examples of the disclosure, and shall all fall within the protection scope of the disclosure. Therefore, the protection scope of the disclosure should be subject to the protection scope of the claims.

We claim:

1. An engineering communication transfer device, comprising:
a communication transfer box, wherein the communication transfer box comprises: a communication input terminal, a first communication output terminal, and a second communication output terminal;
the communication input terminal is connected to a communication cable, wherein the communication cable is connected to a safety monitoring instrument;
the first communication output terminal is connected to an information acquisition instrument; the second communication output terminal is connected to a cable of an external access device; and
the communication transfer box is configured to connect the communication cable to the second communication output terminal when an external access device is connected to the second communication output terminal.

2. The device according to claim 1, wherein the communication transfer box is detachably connected to a control box; and
after connected to the control box, the communication transfer box receives a control signal sent by the control box; and in response to the control signal, controls the communication cable to connect to the external access device, so that the external access device is able to obtain data measured by the safety monitoring instrument.

3. The device according to claim 2, wherein the communication transfer box comprises:
a control switch, wherein the control switch is connected to the communication input terminal, and the control switch is connected to the first communication output terminal in a normal state, and switches to be connected to the second communication output terminal upon receiving of the control signal from the control box.

4. The device according to claim 3, wherein there are a plurality of control switches, which are respectively connected to internal core wires of the communication cable;
the first communication output terminal includes a plurality of first cable core wire connection points, and the second communication output terminal includes a plurality of second cable core wire connection points; and
wherein the first cable core wire connection point is used to connect to an internal core wire of a first cable, and the second cable core wire connection point is used to connect to an internal core wire of a second cable; the first cable is a cable connecting the first communication output terminal and the information acquisition instrument, and the second cable is a cable connecting the second communication output terminal and the external access device.

5. The device according to claim 3, wherein the control switch is a relay.

6. The device according to claim 2, wherein the control box is provided with an external access device interface, and the control box is connected to the external access device through the external access device interface.

7. The device according to claim 2, wherein the communication transfer box is further configured to control the communication cable to connect to the external access device, and cut off a connection to the information acquisition instrument.

8. The device according to claim 2, wherein the control box includes a processor, wherein the processor is connected to the communication transfer box;
a touch-sensitive switch is provided on a housing of the control box, and the touch-sensitive switch is configured to detect a touch operation of a user, and send a detected touch signal to the processor;
wherein, the processor generates a control signal based on the touch signal, and sends the control signal to the communication transfer box; and
wherein, in response to the control signal, the communication transfer box controls the communication cable to connect to the external access device.

9. The device according to claim 8, wherein the processor is further configured to detect a connection status of the external access device, and after determining that a connection is valid, control the control switch to connect to the second communication output terminal.

10. An engineering data acquisition and transmission system, further comprising:
a safety monitoring instrument;
a communication cable;
an information acquisition instrument; and
at least one engineering communication transfer device according to claim 1, wherein the safety monitoring instrument is connected to the communication cable, the communication cable is connected to the engineering communication transfer device, and the engineering communication transfer device is further connected to the information acquisition instrument.

11. The engineering data acquisition and transmission system, as set forth in claim 10, wherein the communication transfer box is detachably connected to a control box, and after connected to the control box, the communication transfer box receives a control signal sent by the control box; and in response to the control signal, controls the communication cable to connect to the external access device, so that the external access device is able to obtain data measured by the safety monitoring instrument.

12. The engineering data acquisition and transmission system as set forth in claim 11, wherein the communication transfer box comprises: a control switch, wherein the control switch is connected to the communication input terminal, and the control switch is connected to the first communication output terminal in a normal state, and switches to be connected to the second communication output terminal upon receiving of the control signal from the control box.

13. The engineering data acquisition and transmission system as set forth in claim 12, wherein there are a plurality of control switches, which are respectively connected to internal core wires of the communication cable; the first communication output terminal includes a plurality of first cable core wire connection points, and the second communication output terminal includes a plurality of second cable core wire connection points; the first cable core wire connection point is used to connect to an internal core wire of a first cable, and the second cable core wire connection point is used to connect to an internal core wire of a second cable; and
the first cable is a cable connecting the first communication output terminal and the information acquisition instrument, and the second cable is a cable connecting the second communication output terminal and the external access device.

14. The engineering data acquisition and transmission system as set forth in 12, wherein the control switch is a relay.

15. The engineering data acquisition and transmission system as set forth in claim 11, wherein the control box is provided with an external access device interface, and the control box is connected to the external access device through the external access device interface.

16. The engineering data acquisition and transmission system as set forth in claim 11, wherein the communication transfer box is further configured to control the communication cable to connect to the external access device, and cut off a connection to the information acquisition instrument.

17. The engineering data acquisition and transmission system as set forth in claim 11, wherein the control box comprises a processor, wherein the processor is connected to the communication transfer box; a touch-sensitive switch is provided on a housing of the control box, and the touch-sensitive switch is configured to detect a touch operation of a user, and send a detected touch signal to the processor; the processor generates a control signal based on the touch signal, and sends the control signal to the communication transfer box; and in response to the control signal, the communication transfer box controls the communication cable to connect to the external access device.

18. The engineering data acquisition and transmission system as set forth in claim 17, wherein the processor is further configured to detect a connection status of the external access device, and after determining that a connection is valid, control the control switch to connect to the second communication output terminal.
